(19) United States
(12) Patent Application Publication
(10) Pub. No.: US 2017/0162378 A1
(43) Pub. Date: Jun. 8, 2017

(54) METHOD OF MANUFACTURING SUBSTRATE FOR EPITAXY

(71) Applicants: Miin-Jang CHEN, Taipei City (TW); GLOBALWAFERS CO., LTD., Hsinchu (TW)

(72) Inventors: Miin-Jang CHEN, Taipei City (TW); Yuan-Chuan CHUANG, Hsinchu City (TW); Huan-Yu SHIH, Hsinchu City (TW); Ying-Ru SHIH, Hsinchu City (TW); Wen-Ching HSU, Hsinchu City (TW)

(21) Appl. No.: 15/365,621

(22) Filed: Nov. 30, 2016

(30) Foreign Application Priority Data
Dec. 8, 2015 (TW) 104141047
Oct. 13, 2016 (TW) 105132969

(51) Int. Cl. H01L 21/02; C23C 16/34; C23C 16/455

(52) U.S. Cl. CPC H01L 21/0234; H01L 21/0262; H01L 21/0254; C23C 16/45525; C23C 16/34

(57) ABSTRACT

A method of manufacturing a substrate for epitaxy is disclosed, including the following steps. Dispose a buffer layer on a base, wherein the buffer layer is constituted by stacked nitride layers formed by the process of atomic layer deposition. The buffer layer could alternatively be constituted by stacked at least one first buffer sub-layer and at least one second buffer sub-layer, wherein the first and second buffer sub-layers are respectively constituted by layered first nitride layers and layered second nitride layers, which are both formed by the process of atomic layer deposition. While forming the buffer layer, perform ion bombardment each time a single layer of the nitride layer, the first nitride layer, or the second nitride layer is formed. Whereby, the base and the buffer layer constitute the substrate for epitaxy, which effectively enhances the crystallinity of the buffer layer.

### BACKGROUND OF THE INVENTION

1. Technical Field

The present invention relates generally to a substrate for epitaxy, and more particularly to a method of manufacturing a substrate for epitaxy.

2. Description of Related Art

Semiconductor components such as semiconductor light-emitting components, high-electron-mobility transistors (HEMT), laser diodes, etc., typically have a buffer layer grown on a base, and an epitaxial layer grown on the buffer layer, wherein the epitaxial layer is structured or patterned to make the semiconductor components. With the buffer layer, the problem of lattice mismatch and the defect density can be eased, and the difference in thermal expansion coefficients between the base and the epitaxial layer can be reduced as well. Whereby, the quality of the epitaxial layer and the efficiency of the semiconductor components can be improved.

Currently, a buffer layer, e.g., AlN or GaN buffer layer, is formed on a base by a metal-organic chemical vapor deposition (MOCVD) process, which has to be performed at a high temperature to crystallize the buffer layer in order to ensure the quality of the buffer layer. However, the required high temperature during the process would not only consume more power for a process machine, but also require a higher standard for the thermal stability of the base.

### BRIEF SUMMARY OF THE INVENTION

In view of the above, the primary objective of the present invention is to provide a method of manufacturing a substrate for epitaxy, which can produce a well crystallized buffer layer in a lower temperature.

The present invention provides a method of manufacturing a substrate for epitaxy, wherein the substrate includes a base and a buffer layer; the method includes the steps of:

A. providing the base; and

B. disposing the buffer layer on a surface of the base, wherein the method of disposing the buffer layer includes the steps of:
B-1. forming a nitride layer by an atomic layer deposition process;
B-2. performing ion bombardment on the nitride layer; and
B-3. repeating steps B-1 and B-2 for multiple times to form stacked nitride layers until the stacked nitride layers reach a predetermined thickness to constitute the buffer layer.

The present invention further provides a method of manufacturing a substrate for epitaxy, wherein the substrate includes a base and a buffer layer; the method includes the steps of:

A. providing the base; and

B. disposing the buffer layer on a surface of the base, wherein the buffer layer includes at least one first buffer layer and at least one second buffer layer which are stacked;

wherein, forming the first buffer layer includes the steps of:
B-1. forming a first nitride layer by an atomic layer deposition process;
B-2. performing ion bombardment on the first nitride layer; and
B-3. repeating steps B-1 and B-2 for multiple times to form stacked first nitride layers until the stacked first nitride layers reach a first predetermined thickness to constitute the first buffer layer;
wherein, forming the second buffer layer includes the steps of:
forming a plurality of stacked second nitride layers by the atomic layer deposition process until the stacked second nitride layers reach a second predetermined thickness to constitute the second buffer layer.

Whereby, manufacturing each nitride layer or first nitride layer by the atomic layer deposition process which requires lower temperature, as well as perform ion bombardment with the plasma on each nitride layer or first nitride layer, can enhance the crystallinity of the buffer layer. Therefore, the crystallization quality of the epitaxial layer grown on the buffer layer can be effectively enhanced, which makes the epitaxial layer be well crystallized.

### BRIEF DESCRIPTION OF THE SEVERAL VIEWS OF THE DRAWINGS

The present invention will be best understood by referring to the following detailed description of some illustrative embodiments in conjunction with the accompanying drawings, in which

FIG. 1 is a schematic diagram of the substrate which is manufactured by a first embodiment of the present invention;

FIG. 2 is a flow chart of the first embodiment, showing the method of manufacturing the substrate for epitaxy;

FIG. 3 are θ-2θ x-ray diffraction patterns of the substrate manufactured by the first embodiment and the substrate served as the control group;

FIG. 4 are θ-2θ x-ray diffraction patterns of the substrates manufactured by the first embodiment with different duration of the ion bombardment, and the substrate served as the control group;

FIG. 5 are θ-2θ x-ray diffraction patterns of the substrates manufactured by the first embodiment with the silicon base and the substrate served as the control group;

FIG. 6 is a flow chart of a second embodiment of the present invention, showing the method of manufacturing the substrate for epitaxy;

FIG. 7 is a schematic diagram of the substrate which is manufactured by the second embodiment;

FIG. 8 are θ-2θ x-ray diffraction patterns of the substrate manufactured by the second embodiment and the substrate served as the control group;

FIG. 9 is a ω-scan rocking curve of the substrate entitled as the sample 1 in FIG. 8;

FIG. 10 are θ-2θ x-ray diffraction patterns of the substrates manufactured by the second embodiment with different duration of the ion bombardment, and different plasma power;

FIG. 11 are θ-2θ x-ray diffraction patterns of the substrates manufactured by the second embodiment with different delay times;

FIG. 12 are x-ray diffraction peak intensities of the four samples in FIG. 11;

FIG. 13 is a cross-sectional high-resolution transmission electron microscopy (HRTEM) image at the interface between the buffer layer and the base of the substrate in FIG. 7;

FIG. 14 is a schematic diagram of the substrate which is manufactured by a third embodiment of the present invention;

FIG. 15 is a flow chart of the third embodiment, showing the method of manufacturing the substrate for epitaxy;

FIG. 16 are ω-scan rocking curves of the substrates manufactured by the first and the third embodiments after the epitaxial layers are grown on the substrates respectively;

FIG. 17 is a schematic diagram of the substrate which is manufactured by a fourth embodiment of the present invention; and

FIG. 18 are ω-scan rocking curve of the substrate and the semi-finished product manufactured by the fourth embodiment.

### DETAILED DESCRIPTION OF THE INVENTION

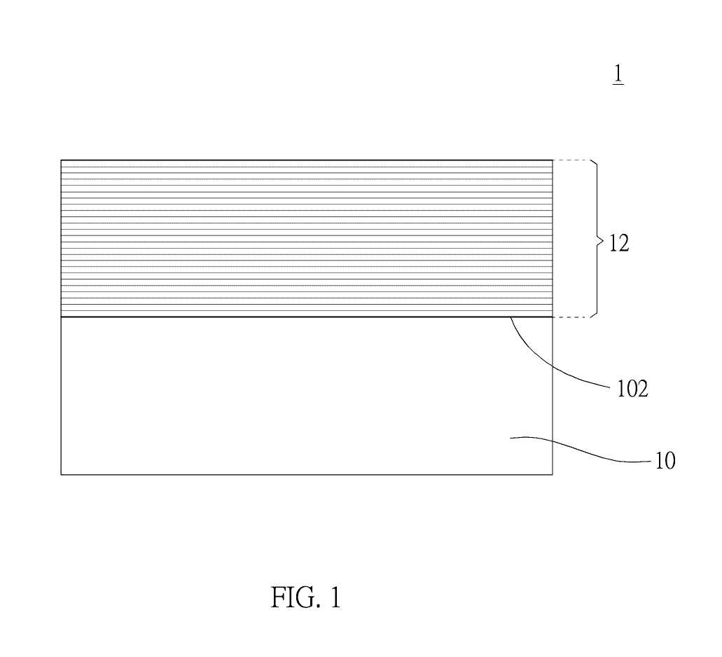

As shown in FIG. 1, the substrate 1 which is manufactured by the first embodiment includes a base 10 and a buffer layer 12, wherein the base 10 is a sapphire base. However, in other embodiments, the base could be silicon base, gallium nitride base, silicon carbide base, or gallium arsenide base. The buffer layer 12 is disposed on a surface 102 of the base 10. An epitaxial layer (not shown), e.g., gallium nitride epitaxial layer, could be grown on the surface of the buffer layer 12.

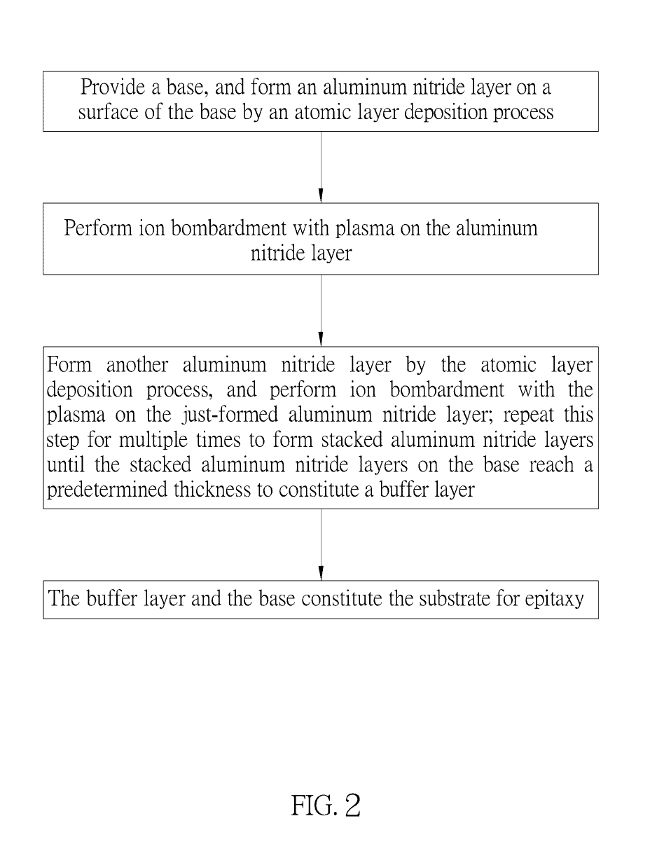

The first embodiment includes the steps shown in FIG. 2 as follows.

First, providing the base 10, and then dispose the buffer layer 12 on a surface 102 of the base 10, wherein the buffer layer 12 has a predetermined thickness. Method of disposing the buffer layer 12 includes the steps as follows.

Form a nitride layer by an atomic layer deposition process (ALD) on the surface 102 of the base 10; in the first embodiment, the nitride layer is an aluminum nitride (AlN) layer, i.e., an aluminum nitride atomic layer. The parameters of the atomic layer deposition process are as follows: the process temperature is 500° C.; trimethylaluminum (TMA): 0.06 seconds; NH₃ plasma: 40 seconds; the aluminum nitride layer has a thickness between 0.1 Å and 3 Å.

Next, perform ion bombardment with plasma on the aluminum nitride layer. In the embodiment, when the process temperature is 500° C., perform ion bombardment with argon gas (Ar) plasma on the aluminum nitride layer to crystallize the aluminum nitride layer, wherein the plasma power is 300 W, and the duration of the ion bombardment is at least 10 seconds. In consideration of the overall process time and the crystallinity of the aluminum nitride layer, the preferable duration of the ion bombardment is between 20 seconds and 40 seconds. Practically, in other embodiments, the plasma can be generated by other kinds of gas, such as N₂, H₂, He, Ne, NH₃, N₂/H₂, N₂O, and CF₄, etc.

Then, use the atomic layer deposition process again to form a new aluminum nitride layer on the aluminum nitride layer which is previously bombarded by ion, and perform ion bombardment with Ar plasma mentioned above on the new aluminum nitride layer. Repeat such steps for multiple times to form stacked aluminum nitride layers on the base 10 until the stacked aluminum nitride layers reach the predetermined thickness of the buffer layer 12. The predetermined thickness is between 5 nm and 200 nm, while in the first embodiment, the predetermined thickness is between 20 nm and 50 nm.

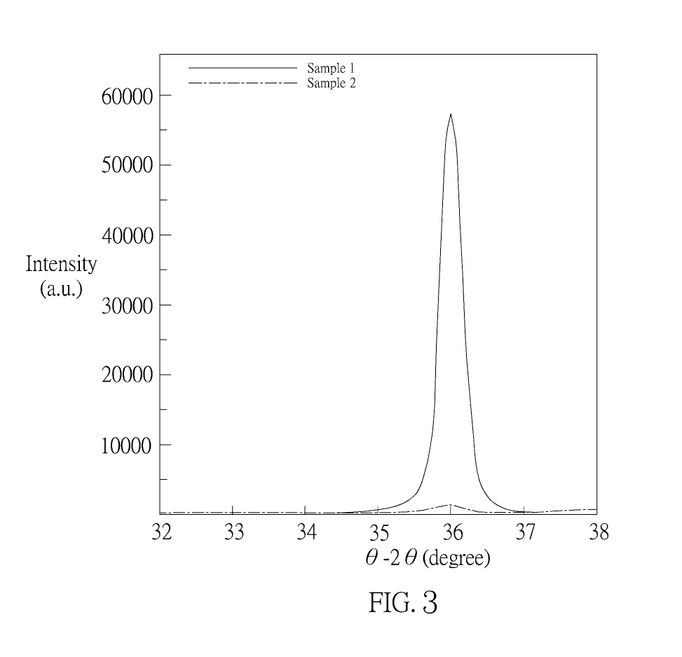

The θ-2θ x-ray diffraction patterns of different substrates are shown in FIG. 3. The sample 1 represents the substrate 1 which is manufactured by the first embodiment, wherein the duration of the Ar ion bombardment is 10 seconds, and the plasma power is 300 W. The sample 2 represents a substrate served as the control group, the buffer layer thereof is also formed by the atomic layer deposition process, while the difference is that, the substrate is aerated by argon for 10 seconds, and the plasma is not generated. It is evident from FIG. 3 that, the crystallinity of the buffer layer 12 of the substrate 1 is enhanced due to the Ar ion bombardments performing on each of the aluminum nitride layers.

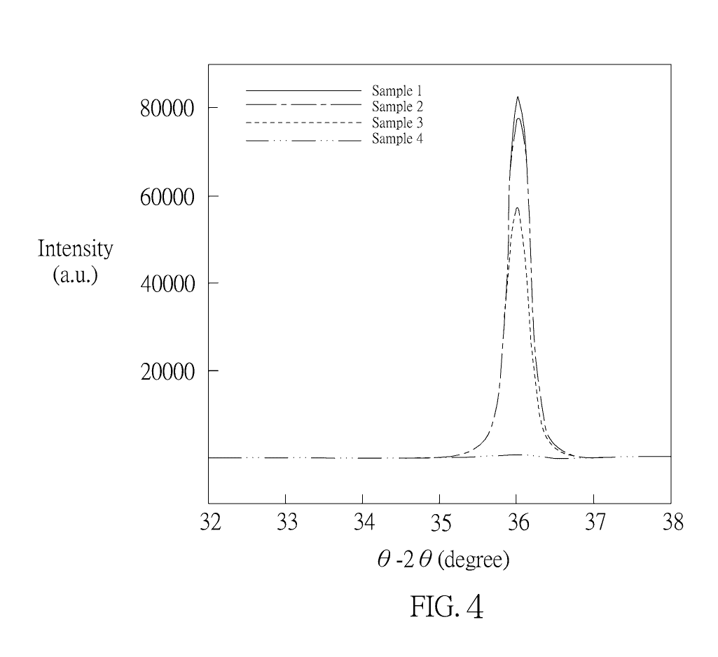

The θ-2θ x-ray diffraction patterns of the substrate 1 with different duration of the ion bombardment are shown in FIG. 4. In the method of manufacturing the sample 1, the duration of each Ar ion bombardment is 40 seconds, and the plasma power is 300 W. In the method of manufacturing the sample 2, the duration of each Ar ion bombardment is 20 seconds, and the plasma power is 300 W. In the method of manufacturing the sample 3, the duration of each Ar ion bombardment is 10 seconds, and the plasma power is 300 W. The sample 4 represents a substrate served as the control group, the buffer layer thereof is also formed by the atomic layer deposition process, while the difference is that, the Ar ion bombardment is not performed. It is evident from FIG. 4 that, the longer the duration of each Ar ion bombardment, the higher the crystallinity of the buffer layer 12. After comparing the sample 1 with sample 2, it is clear that the crystallinity of buffer layer 12 has been little difference if the duration of each ion bombardment is longer than 20 seconds. Therefore, in consideration of the overall process time and the crystallinity of the buffer layer 12, the preferable duration of the ion bombardment is between 20 seconds and 40 seconds.

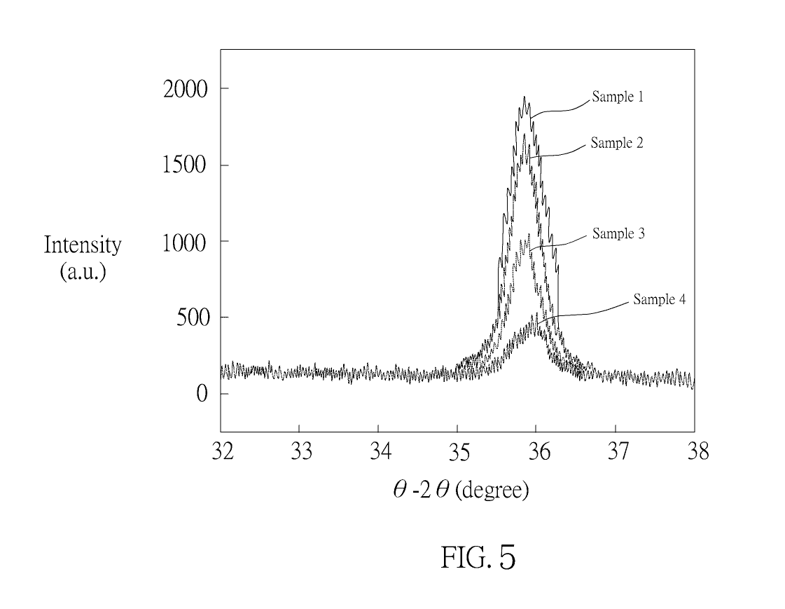

Practically, the base in the first embodiment could be silicon base, wherein the crystal orientation thereof is 111. In FIG. 5, the θ-2θ x-ray diffraction patterns of the substrates manufactured by the first embodiment with the silicon base are shown. In the method of manufacturing the sample 1, the duration of each Ar ion bombardment is 40 seconds, and the plasma power is 300 W. In the method of manufacturing the sample 2, the duration of each Ar ion bombardment is 20 seconds, and the plasma power is 300 W. In the method of manufacturing the sample 3, the duration of each Ar ion bombardment is 10 seconds, and the plasma power is 300 W. The sample 4 represents a substrate served as the control group, the buffer layer thereof is also formed by the atomic layer deposition process, while the difference is that, the Ar ion bombardment is not performed. It is evident from FIG. 5 that, the longer the duration of each Ar ion bombardment, the higher the crystallinity of the buffer layer. After comparing the sample 1 with sample 2, it is clear that the crystallinity of buffer layer has been little difference if the duration of each ion bombardment is longer than 20 seconds. Therefore, in consideration of the overall process time and the crystallinity of the buffer layer, the preferable duration of the ion bombardment is between 20 seconds and 40 seconds.

In the first embodiment, each of the nitride layers constituting the buffer layer 12 is not limited to the aluminum nitride layer, but also can be made of other nitrides, such as GaN, AlₓGa₁₋ₓN, InₓGa₁₋ₓN, InN, AlₓIn_{y}Ga_{1-x-y}N practically.

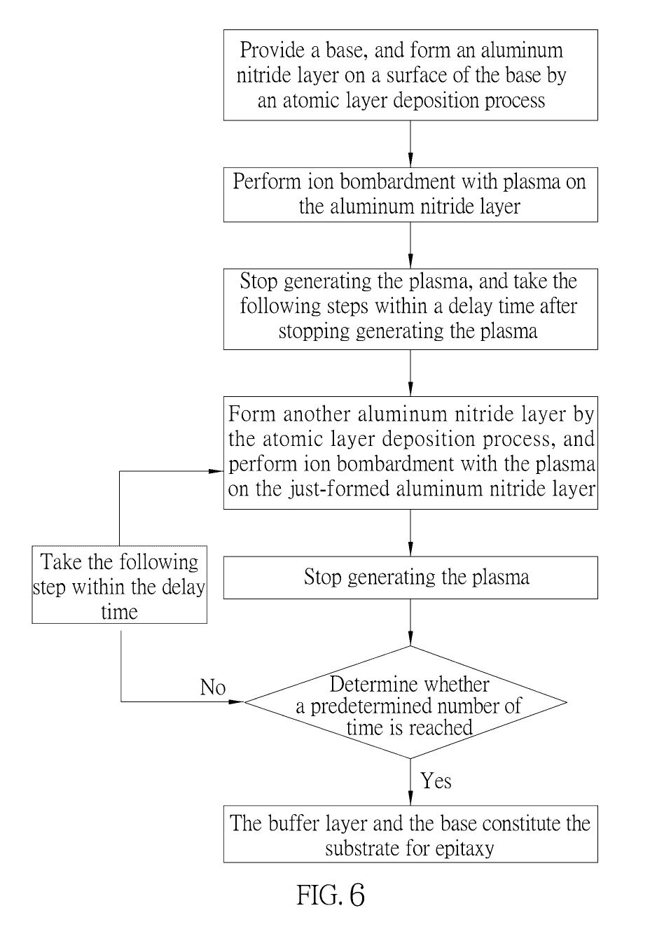

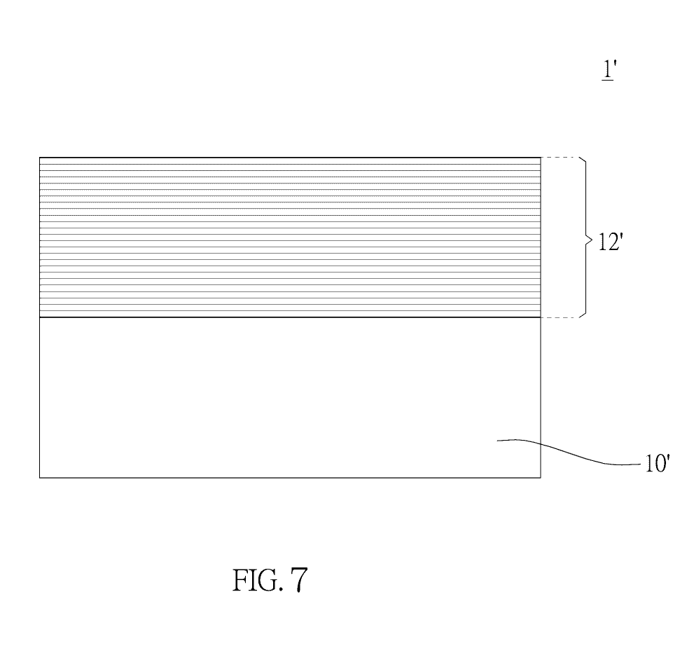

The second embodiment shown in FIG. 6 is adapted to manufacture the substrate 1′ illustrated in FIG. 7. The base 10′ is a sapphire base in the second embodiment, but could also be silicon base, gallium nitride base, silicon carbide base, or gallium arsenide base. The second embodiment has substantially the same steps as the first embodiment, wherein the parameters of the atomic layer deposition process are as follows: the process temperature is 300° C.; TMA: 0.06 seconds; N₂/H₂ plasma: 40 seconds; the aluminum nitride layer has a thickness between 0.1 Å and 3 Å. Comparison with the first embodiment, the difference of the second embodiment is that, after each Ar ion bombardment on one of the aluminum nitride layers, stop generating the plasma. Within a delay time after stopping generating the plasma, form a new aluminum nitride layer by the atomic layer deposition process. In other words, the delay time is the time difference between stopping generating the plasma and re-injecting the TMA. Whereby, the stacked aluminum nitride layers on the base 10′ constitute the buffer layer 12′.

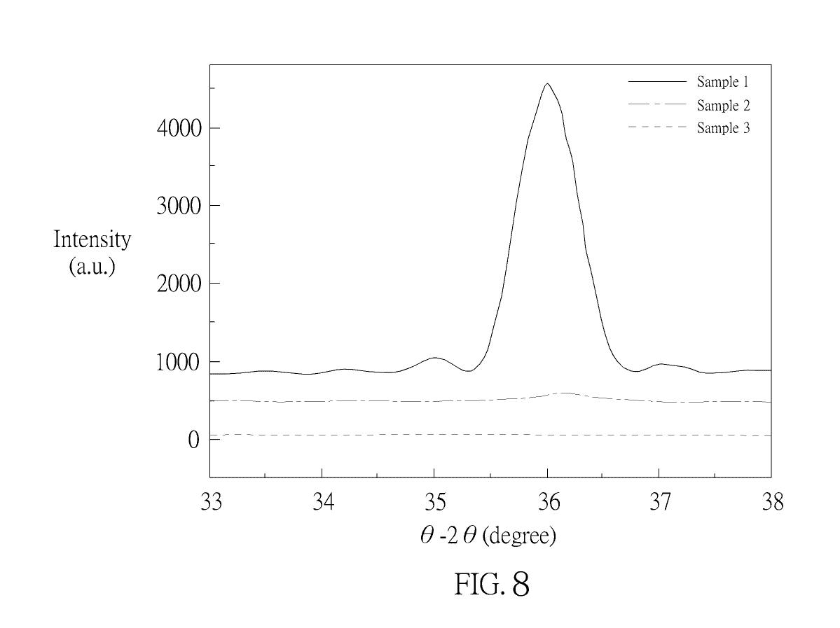

The θ-2θ x-ray diffraction patterns of different substrates are shown in FIG. 8. In the method of manufacturing the sample 1, the duration of each Ar ion bombardment is 20 seconds, and the plasma power is 300 W. The sample 2 represents a substrate served as a control group, the buffer layer thereof is also formed by the atomic layer deposition process, while the difference is that, the Ar ion bombardment is not performed on each of the aluminum nitride layers respectively, but performed on the buffer layer after the buffer layer is formed; wherein the plasma power is 300 W, and the duration of ion bombardment is 4000 seconds. The sample 3 represents a substrate served as another control group, the difference is that, the Ar ion bombardment is not performed on each of the aluminum nitride layers respectively, and is not performed on the buffer layer after the buffer layer is formed either. It is apparent from FIG. 8 that, during the process of manufacturing the substrate 1′, performing Ar ion bombardment on each of the aluminum nitride layers respectively can effectively increase the crystallinity of the buffer layer 12′.

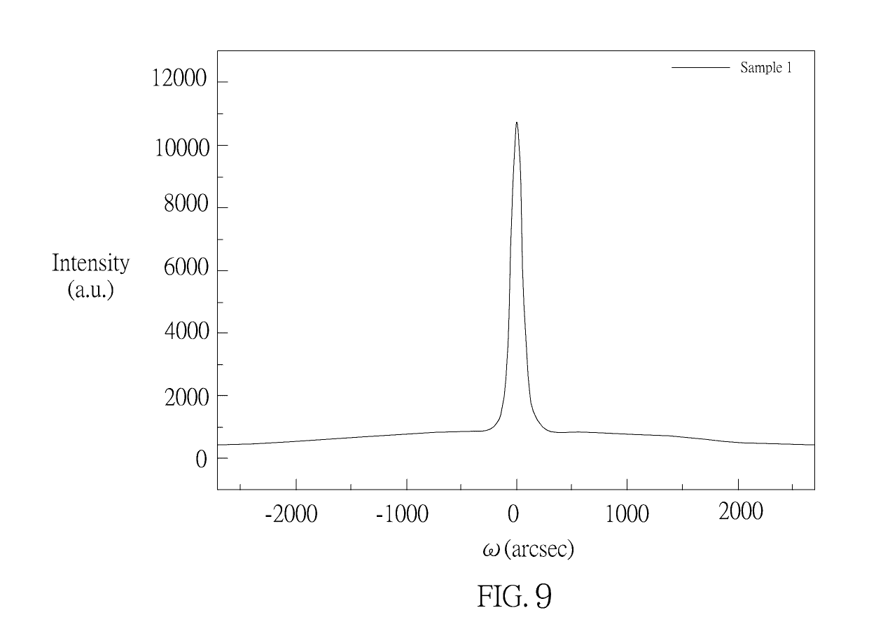

The ω-scan rocking curve of the substrate 1′ entitled as the sample 1 in FIG. 8 is shown in FIG. 9. It is observed from FIG. 9 that, the curve of the sample 1 has a peak in ω-scan, while the curves of the sample 2 and sample 3 have no peak in ω-scan, and thus have not been shown in FIG. 9. It is demonstrated that in the second embodiment, performing Ar ion bombardment can effectively increase the crystallinity of the buffer layer 12′.

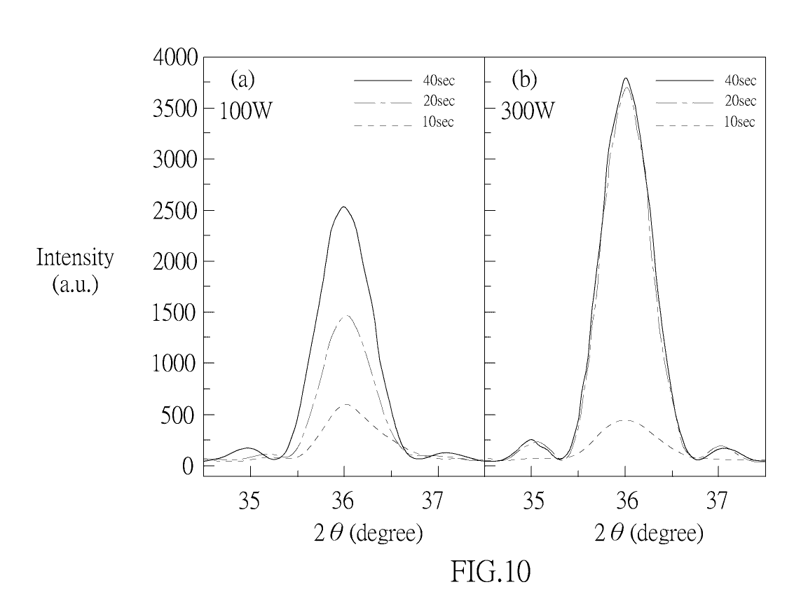

FIG. 10 shows the θ-2θ x-ray diffraction patterns of the substrate 1′ manufactured by the second embodiment with different duration of Ar ion bombardment, and different plasma power. In the left FIG. 10(a), the plasma power is 100 W, and the duration of Ar ion bombardment are 10, 20, and 40 seconds respectively; in the right FIG. 10(b), the plasma power is 300 W, and the duration of Ar ion bombardment are 10, 20, and 40 seconds respectively. It is evident from FIG. 10 that, the longer the duration of Ar ion bombardment on each of the aluminum nitride layers, the higher the crystallinity of the buffer layer 12′. Additionally, the higher the plasma power of Ar ion bombardment, the higher the crystallinity of the buffer layer 12′ as well. If the plasma power is 300 W, the crystallinity of buffer layer 12′ has been little difference between 20 and 40 seconds in duration of ion bombardment. Therefore, it is concluded that the preferable plasma power and duration of ion bombardment are 300 W and al least 20 seconds respectively. In addition, because FIG. 8 and FIG. 10 are obtained from different measuring machines, the intensities of the x-ray diffraction patterns are slightly different.

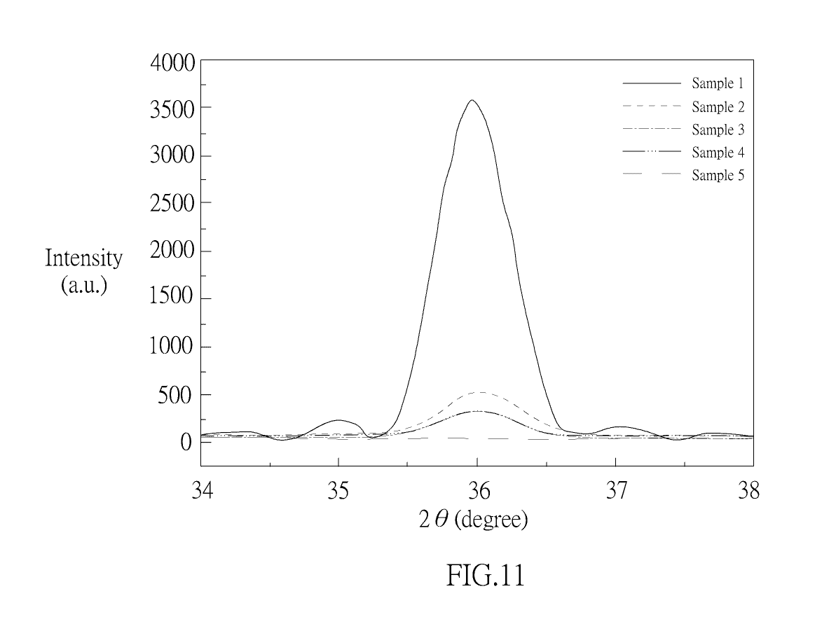

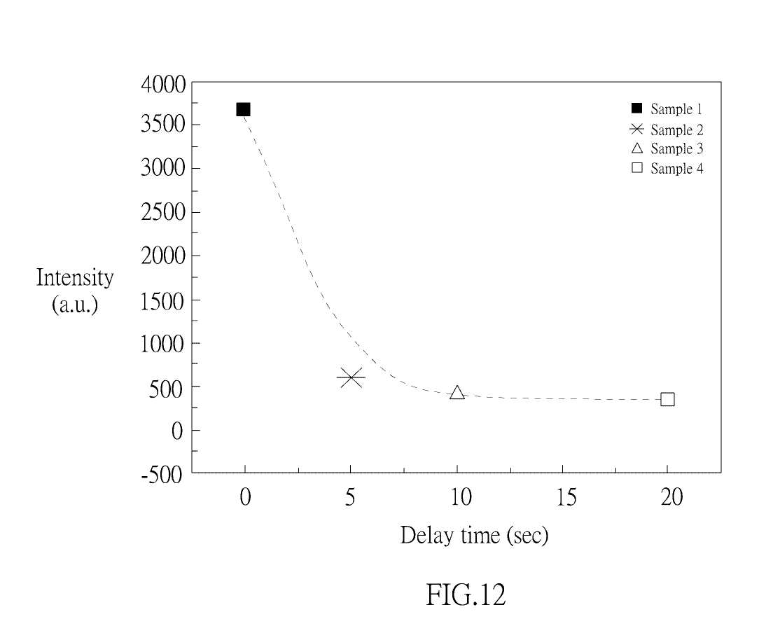

FIG. 11 shows the θ-2θ x-ray diffraction patterns of the substrates 1′ with different delay times, wherein the delay time is the time difference between stopping generating the plasma after performing the Ar ion bombardment for 20 seconds, and forming a new aluminum nitride layer by the atomic layer deposition process. In the method of manufacturing the sample 1, the delay time is 0 second, which means the new aluminum nitride layer is formed immediately after stopping generating the plasma. In the method of manufacturing the sample 2, the delay time is 5 seconds, which means the new aluminum nitride layer is formed after 5 seconds since stopping generating the plasma. In the method of manufacturing the sample 3, the delay time is 10 seconds; for the sample 4, the delay time is 20 seconds. However, in the method of manufacturing the sample 5, the Ar ion bombardment is not performed on each of the aluminum nitride layers respectively, and is not performed on the buffer layer after the buffer layer is formed either. FIG. 12 shows the x-ray diffraction peak intensities of the four samples in FIG. 11. It is obvious from the FIGS. 11 and 12 that, the shorter the delay time, the higher the crystallinity of the buffer layer 12′. Preferably, the delay time is 5 seconds.

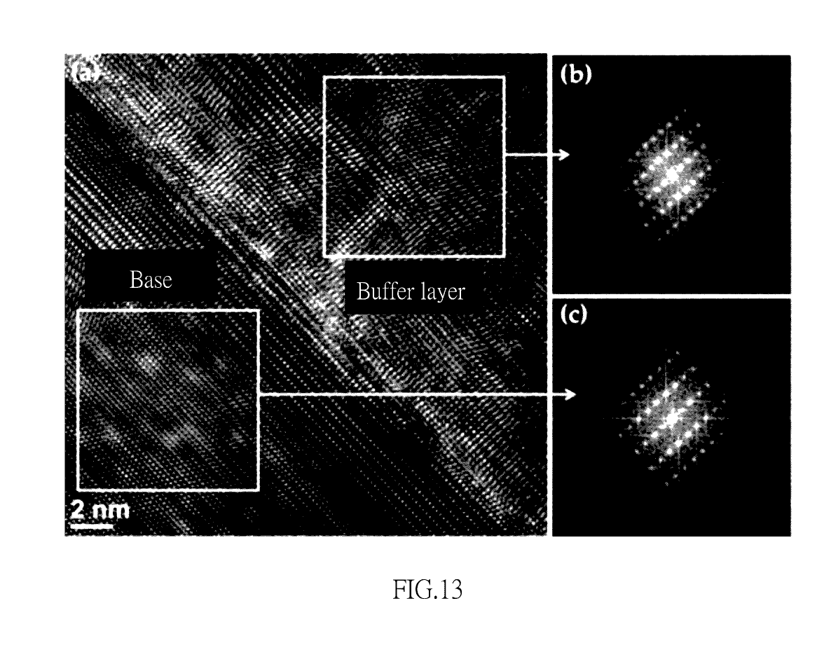

FIG. 13 shows a cross-sectional high-resolution transmission electron microscopy (HRTEM) image at the interface between the buffer layer 12′ and the base 10′. FIGS. 13(b) and 13(c) respectively shows the fast fourier transform (FFT) diffractogram of the areas enclosed in the buffer layer 12′ and the base 10′. It is observed from FIG. 13(a) that the buffer layer 12′ shows an ordered array of atoms, and according to the FFT diffractogram thereof, the buffer layer 12′ has a high-quality single crystal structure, wherein the crystal orientation is [0001]. After comparing FIG. 13(b) with FIG. 13(c), it is known that the epitaxial relationship between the buffer layer 12′ and the base 10′ is that: [0001]buffer layer//[0001]_{base}, and [101̅0]_{buffer layer}/[112̅0]_{base}.

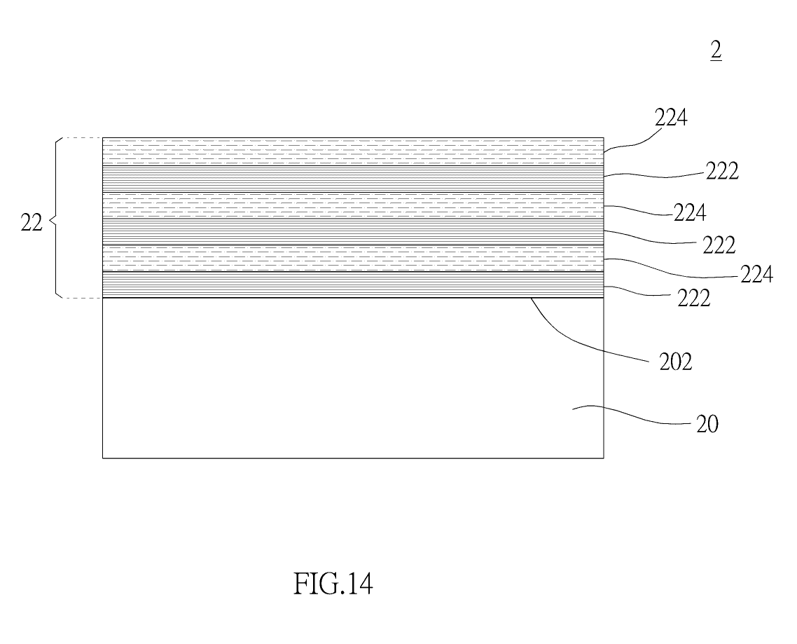

FIG. 14 shows the substrate 2 which is manufactured by the third embodiment. The substrate 2 includes a base 20, and a buffer layer 22, wherein the base 20 is a sapphire base. However, the base 20 could also be silicon base, gallium nitride base, silicon carbide base, or gallium arsenide base. The buffer layer 22 includes a plurality of first buffer layers 222 and a plurality of second buffer layers 224, which are arranged in a staggered manner. In the third embodiment, one of the first buffer layers 222 is formed on the surface 202 of the base 20, while an epitaxial layer (not shown), e.g., gallium nitride epitaxial layer, could be grown on the upmost second buffer layer 224.

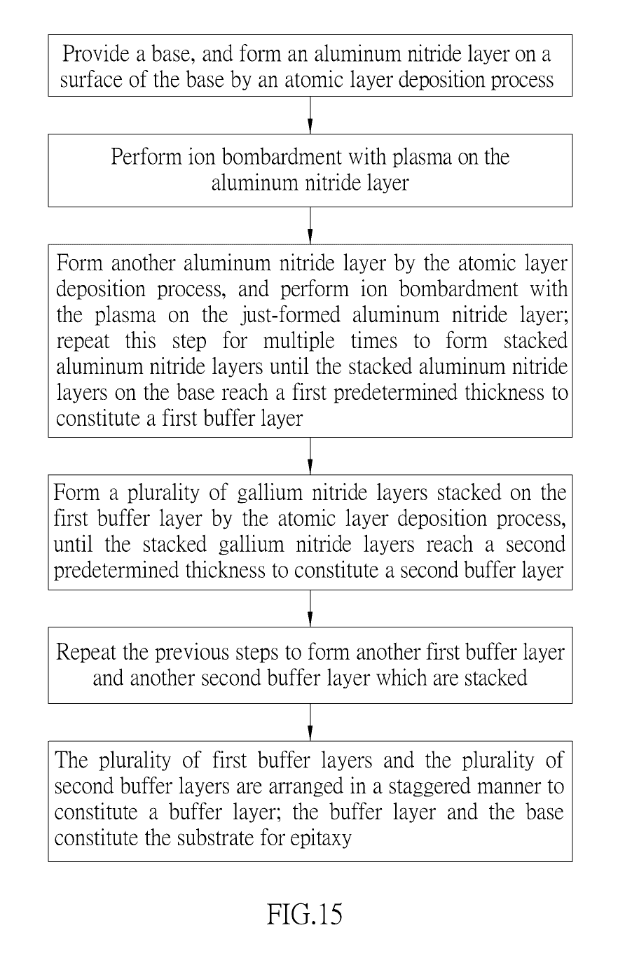

The third embodiment includes the steps shown in FIG. 15 as follows.

First, providing the base 20, and then dispose the buffer layer 22 on a surface 202 of the base 20, wherein the method of disposing each of the first buffer layers 222 includes the steps as follows.

Form a first nitride layer by an atomic layer deposition process (ALD) on the surface 202 of the base 20; in the embodiment, the first nitride layer is an aluminum nitride (AlN) layer, i.e., an aluminum nitride atomic layer. The parameters of the atomic layer deposition process are as follows: the process temperature is 500° C.; trimethylaluminum (TMA): 0.06 seconds; NH₃ plasma: 40 seconds; the aluminum nitride layer has a thickness between 0.1 Å and 3 Å.

Next, perform ion bombardment with plasma on the aluminum nitride layer. In the embodiment, when the process temperature is 500° C., perform ion bombardment with argon gas (Ar) plasma on the aluminum nitride layer to crystallize the aluminum nitride layer, wherein the plasma power is 300 W, and the duration of the ion bombardment is at least 10 seconds. In consideration of the overall process time and the crystallinity of the aluminum nitride layer, the preferable duration of the ion bombardment is between 20 seconds and 40 seconds. Practically, in other embodiments, the plasma can be generated by other kinds of gas, such as N₂, H₂, He, Ne, NH₃, N₂/H₂, N₂O, and CF₄, etc.

Then, use the atomic layer deposition process again to form a new aluminum nitride layer on the aluminum nitride layer which is previously bombarded by ion, and perform ion bombardment with Ar plasma mentioned above on the new aluminum nitride layer. Repeat such steps for multiple times to form stacked aluminum nitride layers on the base 20 until the stacked aluminum nitride layers reach a first predetermined thickness. The first predetermined thickness is between 1 nm and 50 nm, while in the third embodiment, the first predetermined thickness is 3.9 nm. Whereby, the stacked aluminum nitride layers constitute one of the first buffer layers.

Next, form one of the second buffer layers 224 on the first buffer layer 222, wherein forming the second buffer layer 224 includes the steps as follows. Form a plurality of stacked second nitride layers by the atomic layer deposition process until the stacked second nitride layers reach a second predetermined thickness to constitute one of the second buffer layers, wherein in the embodiment, each of the second nitride layers is gallium nitride (GaN) layer, i.e., gallium nitride atomic layer; the second predetermined thickness is between 1 nm and 50 nm. The parameters of the atomic layer deposition process for each gallium nitride layer are as follows: the process temperature is 500° C.; triethylagallium (TEGa): 0.1 seconds; gas plasma mixed by NH₃ and hydrogen: 20 seconds; each of the gallium nitride layers has a thickness between 0.1 Å and 3 Å. In the embodiment, ion bombardment with Ar plasma is not performed on the just-formed gallium nitride layer.

Afterwards, repeat multiple times of forming stacked another one of the first buffer layers 222 and another one of the second buffer layers 224. Whereby, the first buffer layers 222 and the second buffer layers 224 arranged in a staggered manner constitute the buffer layer 22, which is formed on the base 20. In the third embodiment, the buffer layer 22 is formed by three pairs of first buffer layer 222 and second buffer layer 224 stacked together. Additionally, because each of the gallium nitride layers of the second buffer layer 224 is not bombarded by ion, the crystallinity of the second buffer layer 224 is lower than that of the first buffer layer 222. Accordingly, the second buffer layer 224 can further serve as an absorbing layer for defects and stress, which reduces the possibility that defects penetrate into the epitaxial layer after the epitaxial layer is grown on the buffer layer 22.

Practically, the third embodiment can also include the step of stopping generating the plasma after ion bombardment on each of the aluminum nitride layers, and within a delay time after stopping generating the plasma, form a new aluminum nitride layer by the atomic layer deposition process, which are described in the second embodiment. Preferably, the delay time is 5 seconds.

In addition, the method of manufacturing each of the second buffer layers 224 in the third embodiment can also include the step of performing ion bombardment with plasma on each just-formed gallium nitride layer, which crystallizes the gallium nitride layers of the second buffer layer 224, in order to increase the crystallinity of the buffer layer 222. The plasma is formed by Ar, N₂, H₂, He, Ne, NH₃, N₂/H₂, N₂O, or CF₄. Practically, the third embodiment can also include the step of stopping generating the plasma after ion bombardment on each of the gallium nitride layers, and within a delay time after stopping generating the plasma, form a new gallium nitride layer by the atomic layer deposition process, which are described in the second embodiment. Preferably, the delay time is 5 seconds.

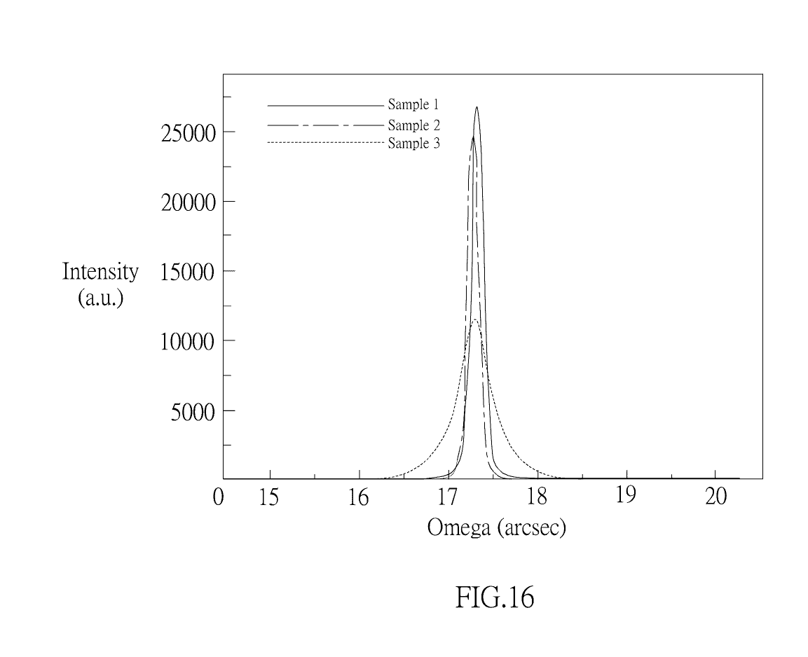

FIG. 16 shows the ω-scan rocking curves of the substrate 2 manufactured by the third embodiment and the substrate 1 manufactured by the first embodiment after the gallium nitride epitaxial layers are grown on the substrates respectively. The gallium nitride epitaxial layer is grown by metal-organic chemical vapor deposition (MOCVD) at a high temperature of 1180° C. First, the substrates 1 and 2 are annealed in an ammonia atmosphere for five minutes within a MOCVD chamber. Next, growing a 1.5 μm gallium nitride epitaxial layer on the substrates 1 and 2. In FIG. 16, sample 1 includes the substrate 2, wherein the second predetermined thickness of each of the second buffer layers 224 thereof is 3.5 nm; in the method of manufacturing the sample 1, the duration of each Ar ion bombardment on the aluminum nitride layer is 40 seconds, and the plasma power is 300 W. Sample 2 also includes the substrate 2, while the second predetermined thickness of each of the second buffer layers 224 thereof is 1.8 nm; in the method of manufacturing the sample 2, the duration of each Ar ion bombardment on the aluminum nitride layer is 40 seconds, and the plasma power is 300 W, which are the same as the sample 1. Sample 3 includes the substrate 1, and in the method of manufacturing the sample 3, the duration of each Ar ion bombardment on the aluminum nitride layer is 40 seconds, and the plasma power is 300 W. It is apparent from FIG. 16 that compared with the substrate 1, the manufacturing method of substrate 2 can effectively enhance the crystallization quality and crystallinity of the epitaxial layer grown on the buffer layer.

Practically, the position of the first buffer layers 222 can exchange with that of the second buffer layers 224, and the manufacturing method thereof is approximately the same, while the difference is that disposing one of the second buffer layers 224 on the surface of the base 20 first, and disposing one of the first buffer layers 222 next, and then performing ion bombardment. Because each of the gallium nitride layers of the second buffer layer 224 is not bombarded by ion, the crystallinity of the second buffer layer 224 is lower than that of the first buffer layer 222. Accordingly, the second buffer layer 224 can further serve as an absorbing layer for defects and stress, which result from lattice mismatch, whereby to reduce the possibility that defects penetrate into the epitaxial layer after the epitaxial layer is grown on the buffer layer 22. Additionally, the number of the first buffer layer 222 and the second buffer layer 224 can be one at least respectively.

In the third embodiment, each of the first nitride layers constituting the first buffer layer 222 is not limited to the aluminum nitride layer, but also can be made of other nitrides, such as GaN, AlₓGa₁₋ₓN, InₓGa₁₋ₓN, InN, AlₓIn_{y}Ga_{1-x-y}N practically. Also, each of the second nitride layers constituting the second buffer layers 224 is not limited to the gallium nitride layer, but also can be made of the abovementioned nitrides, such as GaN, AlₓGa₁₋ₓN, InₓGa₁₋ₓN, InN, AlₓIn_{y}Ga_{1-x-y}N practically. In addition, materials of each first nitride layer and each second nitride layer can be different or the same.

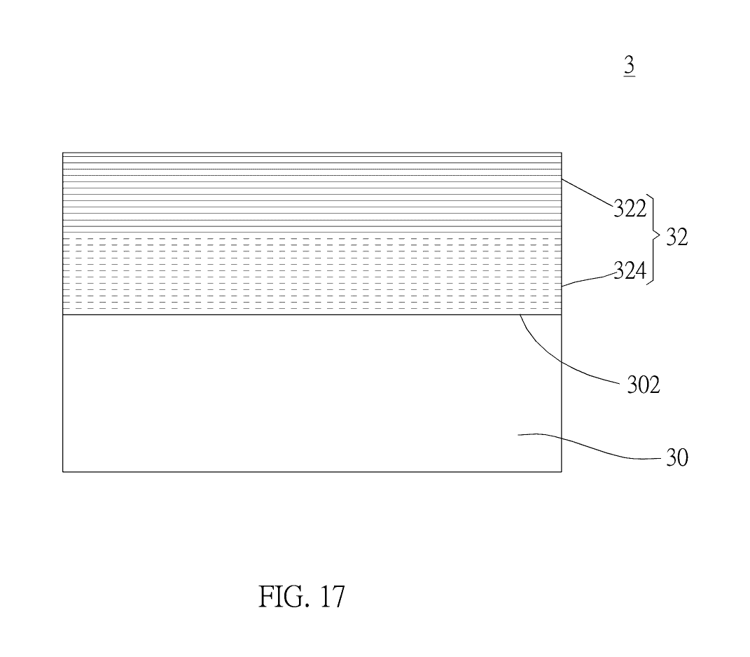

FIG. 17 shows the substrate 3 which is manufactured by the fourth embodiment. The substrate 3 includes a base 30 and a buffer layer 32, which are substantially the same as the substrate 2. The base 10 is a sapphire base, however, in other embodiments, the base could be silicon base, gallium nitride base, silicon carbide base, or gallium arsenide base. Compared with the substrate 2, the buffer layer 32 of the substrate 3 includes stacked at least one first buffer layer 322 and stacked at least one second buffer layer 324, wherein the materials of the first buffer layer 322 and the second buffer layer 324 are the same, and the thickness of the first and the second buffer layer 322, 324 are 18 nm. The fourth embodiment has substantially the same steps as the third embodiment, while the difference is that the fourth embodiment includes the steps as follows. First, dispose the second buffer layer 324 on the surface 302 of the base 30 by an atomic layer deposition process, wherein each of the second nitride layers of the second buffer layer 324 is an aluminum nitride layer, and each second nitride layer is not bombarded by ion. Next, dispose the first buffer layer 322 on the second buffer layer 324 by the atomic layer deposition process, wherein each of the first nitride layers of the first buffer layer 322 is also an aluminum nitride layer, and then perform ion bombardment with plasma on each of the first nitride layers after each first nitride layer is formed. Afterwards, within a delay time after stopping generating the plasma, form a new first nitride layer, wherein the delay time is 5 seconds.

In practice, if the number of both the first buffer layer 322 and the second buffer layer 324 are more than one, the buffer layers would arranged in a staggered manner as shown in FIG. 14. The difference is that the second buffer layer 324 is in touch with the surface 302 of the base 30.

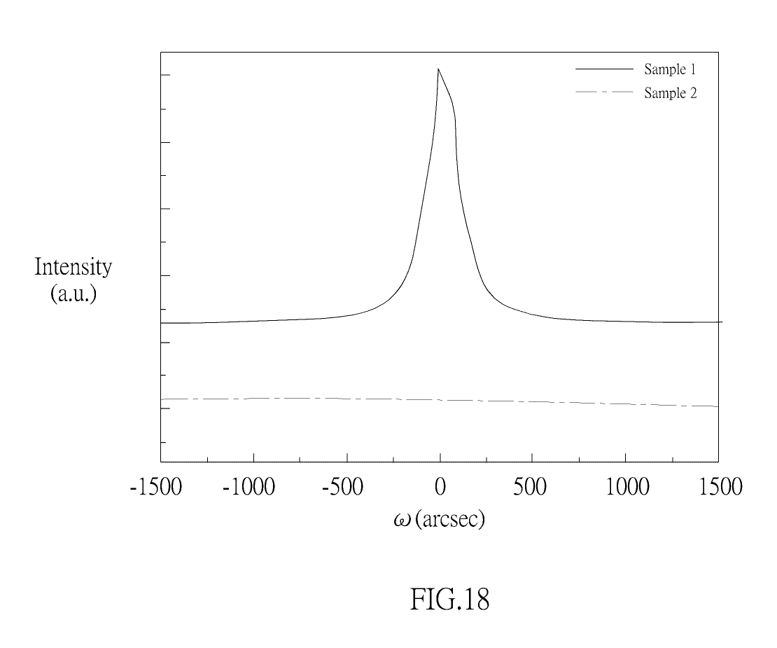

FIG. 18 shows the ω-scan rocking curves of different substrates. Sample 1 represents the substrate 3, wherein the first buffer layer 322 and the second buffer layer 324 are grown at a temperature of 400° C., and the duration of each ion bombardment on each of the first nitride layers of the first buffer layer 322 with 300 W Ar plasma is 20 seconds. Sample 2 is the semi-finished product of the substrate 3, and includes the base 30 and the second buffer layer 324, wherein the second buffer layer 324 is disposed on the base 30, and is not bombarded by ion. It is clear from FIG. 18 that the curve of the sample 1 has a peak, which demonstrates that in the fourth embodiment, performing ion bombardment with plasma on each first nitride layer of the first buffer layer 322 can well crystallize the first buffer layer 322. In contrast, the curve of the sample 2 has no peak, which represents the crystallinity of the second buffer layer 324 which is not bombarded by ion is lower than that of the first buffer layer 322. Accordingly, the second buffer layer 324 can serve as an absorbing layer for defects and stress, in order to ease such defects and stress resulting from lattice mismatch.

In conclusion, the method of manufacturing the substrate for epitaxy includes manufacturing the aluminum nitride layer by the atomic layer deposition process which requires lower temperature. Additionally, performing ion bombardment on each aluminum nitride layer serves as an annealing process, which makes the aluminum nitride layer more compact, and crystallizes the aluminum nitride layers of the buffer layer in order to enhance the crystallinity of the buffer layer.

It must be pointed out that the embodiments described above are only some preferred embodiments of the present invention. All equivalent methods which employ the concepts disclosed in this specification and the appended claims should fall within the scope of the present invention.

What is claimed is:

1. A method of manufacturing a substrate for epitaxy, wherein the substrate comprises a base and a buffer layer; comprising the steps of:
A. providing the base; and
B. disposing the buffer layer on a surface of the base, wherein the method of disposing the buffer layer comprises the steps of:
B-1. forming a nitride layer by an atomic layer deposition process;
B-2. performing ion bombardment on the nitride layer; and
B-3. repeating steps B-1 and B-2 for multiple times to form stacked nitride layers until the stacked nitride layers reach a predetermined thickness to constitute the buffer layer.

2. The method of claim 1, wherein the ion bombardment is performed with a plasma formed by a gas selected from the group consisting of Ar, N₂, H₂, He, Ne, NH₃, N₂/H₂, N₂O, and CF₄.

3. The method of claim 1, wherein the ion bombardment is performed with a plasma bombarding on the nitride layer in step B-2, and lasts for at least 10 seconds.

4. The method of claim 1, wherein the nitride layer formed in step B-1 has a thickness between 0.1 Å and 3 Å.

5. The method of claim 1, wherein performing ion bombardment crystallizes the nitride layer in step B-2.

6. The method of claim 1, wherein the ion bombardment is performed with a plasma bombarding on the nitride layer in step B-2; before taking step B-3, the method further comprises the step of stopping generating the plasma, and taking step B-3 within a delay time after stopping generating the plasma, wherein the delay time is 5 seconds.

7. A method of manufacturing a substrate for epitaxy, wherein the substrate comprises a base and a buffer layer; comprising the steps of:
A. providing the base; and
B. disposing the buffer layer on a surface of the base, wherein the buffer layer comprises at least one first buffer layer and at least one second buffer layer which are stacked;
wherein, forming the first buffer layer comprises the steps of:
B-1. forming a first nitride layer by an atomic layer deposition process;
B-2. performing ion bombardment on the first nitride layer; and
B-3. repeating steps B-1 and B-2 for multiple times to form stacked first nitride layers until the stacked first nitride layers reach a first predetermined thickness to constitute the first buffer layer;
wherein, forming the second buffer layer comprises the steps of:
forming a plurality of stacked second nitride layers by the atomic layer deposition process until the stacked second nitride layers reach a second predetermined thickness to constitute the second buffer layer.

8. The method of claim 7, wherein the ion bombardment is performed with a plasma formed by a gas selected from the group consisting of Ar, N₂, H₂, He, Ne, NH₃, N₂/H₂, N₂O, and CF₄.

9. The method of claim 7, wherein the ion bombardment is performed with a plasma bombarding on the first nitride layer in step B-2, and lasts for at least 10 seconds.

10. The method of claim 7, wherein the at least one first buffer layer and at least one second buffer layer in step B comprise a plurality of first buffer layers and a plurality of second buffer layers; the first buffer layers and the second buffer layers are arranged in a staggered manner.

11. The method of claim 10, wherein forming the second buffer layer further comprises the steps of:
performing ion bombardment on the just-formed second nitride layer after forming each of the second nitride layers, wherein each of the second nitride layers has a thickness between 0.1 Å and 3 Å.

12. The method of claim 11, wherein the ion bombardment on the second nitride layers is performed with a plasma formed by a gas selected from the group consisting of Ar, N₂, H₂, He, Ne, NH₃, N₂/H₂, N₂O, and CF₄.

13. The method of claim 7, wherein a material of the first nitride layers is different from a material of the second nitride layers.

14. The method of claim 7, wherein materials of the first nitride layers and the second nitride layers are the same.

15. The method of claim 7, wherein the first nitride layer formed in step B-1 has a thickness between 0.1 Å and 3 Å.

16. The method of claim 7, wherein performing ion bombardment crystallizes the first nitride layer in step B-2.

17. The method of claim 7, wherein the ion bombardment is performed with a plasma bombarding on the first nitride layer in step B-2; before taking step B-3, the method further comprises the step of stopping generating the plasma, and taking step B-3 within a delay time after stopping generating the plasma, wherein the delay time is 5 seconds.

18. The method of claim 7, wherein one of the second buffer layers without performing ion bombardment is disposed on the surface of the base first.
